(19) United States
(12) Patent Application Publication
(10) Pub. No.: US 2024/0243100 A1
(43) Pub. Date: Jul. 18, 2024

(54) SEMICONDUCTOR DEVICE

(71) Applicant: Rohm Co., Ltd., Kyoto-shi (JP)

(72) Inventor: Bungo TANAKA, Kyoto-shi (JP)

(21) Appl. No.: 18/618,790

(22) Filed: Mar. 27, 2024

Related U.S. Application Data
(63) Continuation of application No. PCT/JP2022/039455, filed on Oct. 24, 2022.

(30) Foreign Application Priority Data
Nov. 18, 2021 (JP) 2021-187872

(51) Int. Cl. H01L 25/065; H01L 23/00; H01L 23/10; H01L 23/31; H01L 23/495

(52) U.S. Cl. CPC H01L 25/0655; H01L 23/10; H01L 23/3135; H01L 23/49513; H01L 24/48; H01L 23/49541; H01L 24/45; H01L 2224/45144; H01L 2224/48137; H01L 2224/48245; H01L 2924/1424; H01L 2924/14252

(57) ABSTRACT

A semiconductor device includes a first semiconductor element formed with a step-down circuit, a first lead electrically connected to the first semiconductor element, and a second lead electrically connected to the first semiconductor element and spaced apart from the first lead in a first direction. The semiconductor device additionally includes a sealing resin covering the first semiconductor element and a portion of each of the first lead and the second lead. The sealing resin includes a recess formed between the first lead and the second lead in the first direction. As viewed in the first direction, the recess overlaps with the first lead and the second lead.

### TECHNICAL FIELD

The present disclosure relates to semiconductor devices.

### BACKGROUND ART

In recent years, electric vehicles have been increasingly common. JP-A-2012-95427 discloses an example of a circuit arrangement for monitoring the voltage of a vehicle-mounted battery and controlling an inverter. Such a circuit can be used to prevent excessive voltage from being applied to an inverter that drives a motor.

Among the circuits disclosed in JP-A-2012-95427, a resistor voltage detecting circuit and a high-voltage battery detecting circuit are relevant for monitoring the voltage of a vehicle-mounted battery. These two circuits are composed of a plurality of ICs. The two circuits disclosed in JP-A-2012-95427 can be made more compact by building the circuits with a minimum number of ICs and incorporating the circuits into a single semiconductor device together with a plurality of leads electrically connected to the ICs. Note, however, that some leads of the semiconductor device are connected to the battery and thus subjected to high voltages. Reducing the size of the semiconductor device often involves reducing the pitch of leads, which can result in a risk of discharge between the leads when a high voltage is applied.

### BRIEF DESCRIPTION OF THE DRAWINGS

FIG. 1 is a plan view of a semiconductor device according to a first embodiment of the present disclosure.

FIG. 2 is a plan view corresponding to FIG. 1, with the sealing resin shown as transparent.

FIG. 3 is a bottom view of the semiconductor device shown in FIG. 1.

FIG. 4 is a front view of the semiconductor device shown in FIG. 1.

FIG. 5 is a rear view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a block diagram of a circuit formed in the semiconductor device shown in FIG. 1.

FIG. 10 is a partially enlarged plan view of a semiconductor device that is a variation of the device shown in FIG. 1.

FIG. 11 is a plan view of a semiconductor device according to a second embodiment of the present disclosure.

FIG. 12 is a bottom view of the semiconductor device shown in FIG. 11.

FIG. 13 is a sectional view taken along line XIII-XIII in FIG. 11.

FIG. 14 is a sectional view taken along line XIV-XIV in FIG. 11.

FIG. 15 is a plan view of a semiconductor device according to a third embodiment of the present disclosure.

FIG. 16 is a sectional view taken along line XVI-XVI in FIG. 15.

FIG. 17 is a sectional view taken along line XVII-XVII in FIG. 15.

FIG. 18 is a plan view of a semiconductor device according to a fourth embodiment of the present disclosure.

FIG. 19 is a sectional view taken along line XIX-XIX in FIG. 18.

FIG. 20 is a sectional view taken along line XX-XX in FIG. 18.

FIG. 21 is a sectional view taken along line XXI-XXI in FIG. 18.

FIG. 22 is a plan view of a semiconductor device according to a fifth embodiment of the present disclosure.

FIG. 23 is a sectional view taken along line XXIII-XXIII in FIG. 22.

FIG. 24 is a sectional view taken along line XXIV-XXIV in FIG. 22.

FIG. 25 is a plan view of a semiconductor device according to a sixth embodiment of the present disclosure.

FIG. 26 is a plan view corresponding to FIG. 25, with the sealing resin shown as transparent.

FIG. 27 is a sectional view taken along line XXVII-XXVII in FIG. 26.

FIG. 28 is a sectional view taken along line XXVIII-XXVIII in FIG. 26.

FIG. 29 is a sectional view taken along line XXIX-XXIX in FIG. 26.

FIG. 30 is a plan view of a semiconductor device that is a variation of the device shown in FIG. 25.

FIG. 31 is a plan view of a semiconductor device according to a seventh embodiment of the present disclosure.

FIG. 32 is a sectional view taken along line XXXII-XXXII in FIG. 31.

FIG. 33 is a sectional view taken along line XXXIII-XXXIII in FIG. 31.

### DETAILED DESCRIPTION OF EMBODIMENTS

Embodiments of the present disclosure will be described with reference to the attached drawings.

### First Embodiment

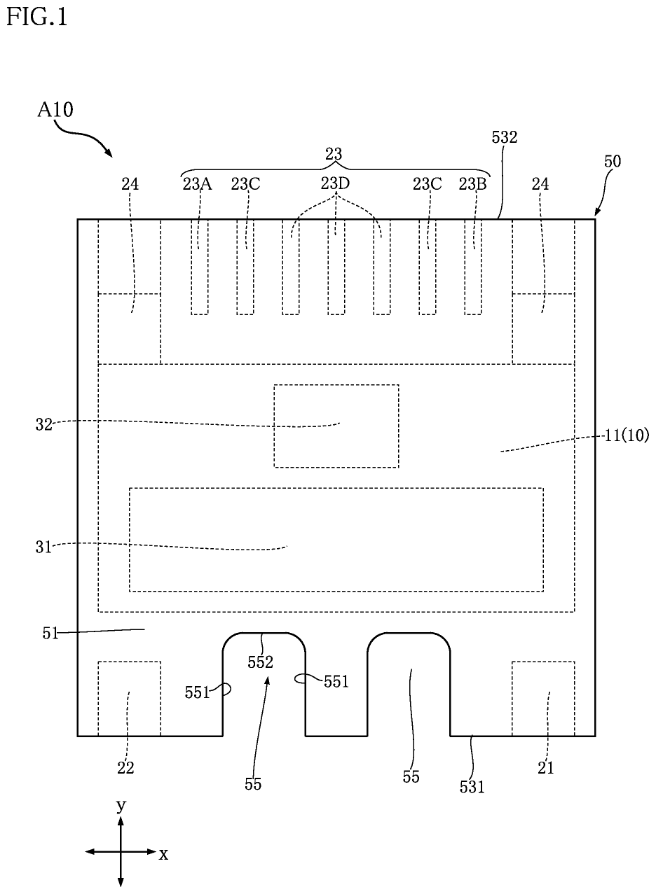

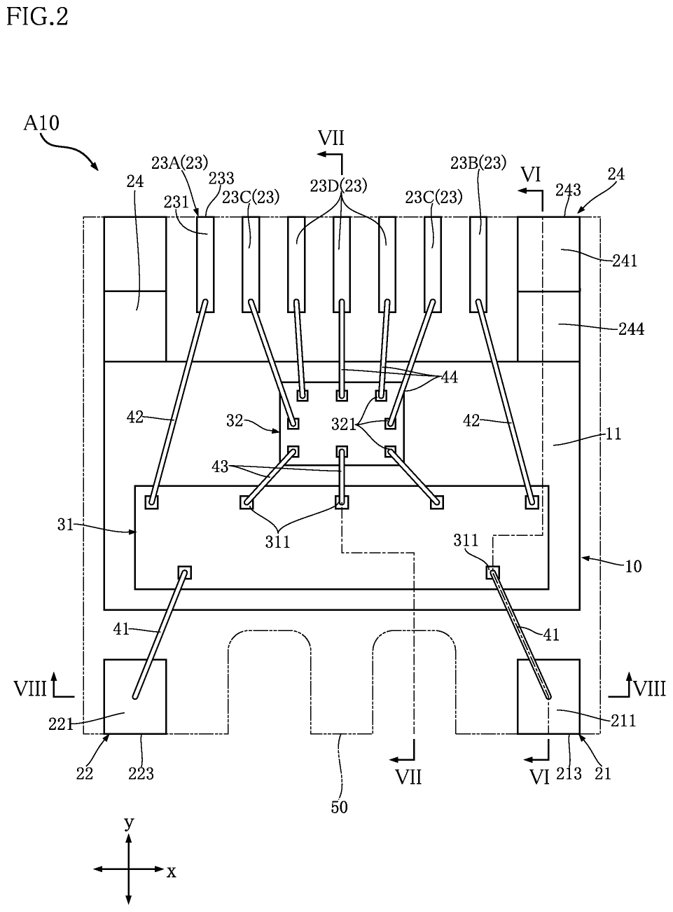

With reference to FIGS. 1 to 8, the following describes a semiconductor device A10 according to a first embodiment of the present disclosure. In one example, the semiconductor device A10 is used for monitoring the voltage of a battery mounted on an electric vehicle. The semiconductor device A10 is in a quad flat non-leaded (QFN) package. The semiconductor device A10 includes a die pad 10, a first lead 21, a second lead 22, a plurality of third leads 23, two fourth leads 24, a first semiconductor element 31, a second semiconductor element 32, and a sealing resin 50. For convenience, FIG. 2 shows the sealing resin 50 as transparent, with the outline of the sealing resin 50 indicated by imaginary lines (two-dot-dash lines). FIG. 2 also shows lines VI-VI and VII-VII with dot-dash lines.

For convenience in describing the semiconductor device A10, the direction in which the first lead 21 and the second lead 22 are separated is referred to as a “first direction x”. A direction orthogonal to the first direction x is referred to as a “second direction y”. The direction orthogonal to the first direction x and the second direction y is referred to as a “third direction z”. The third direction z corresponds to the thickness direction of the first lead 21 and the second lead 22.

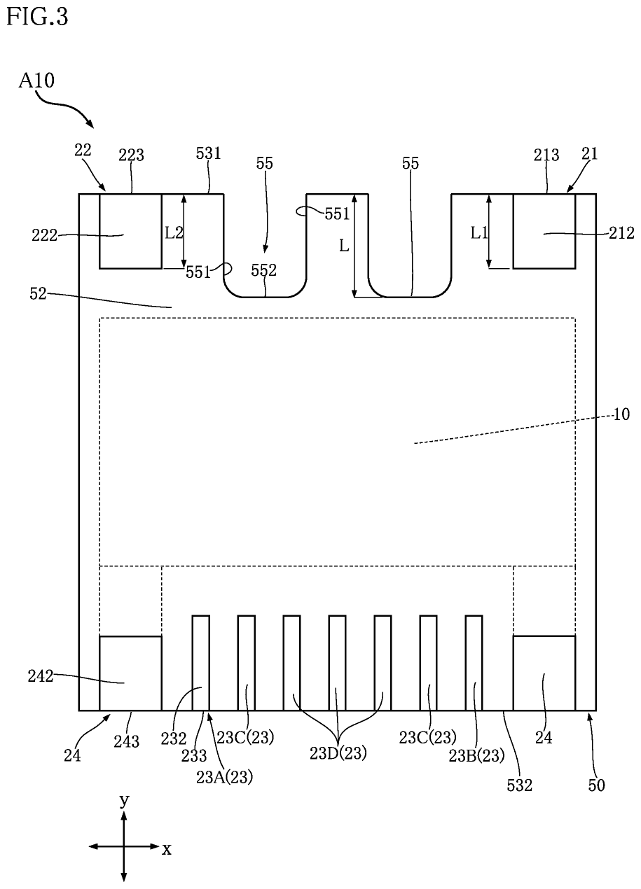

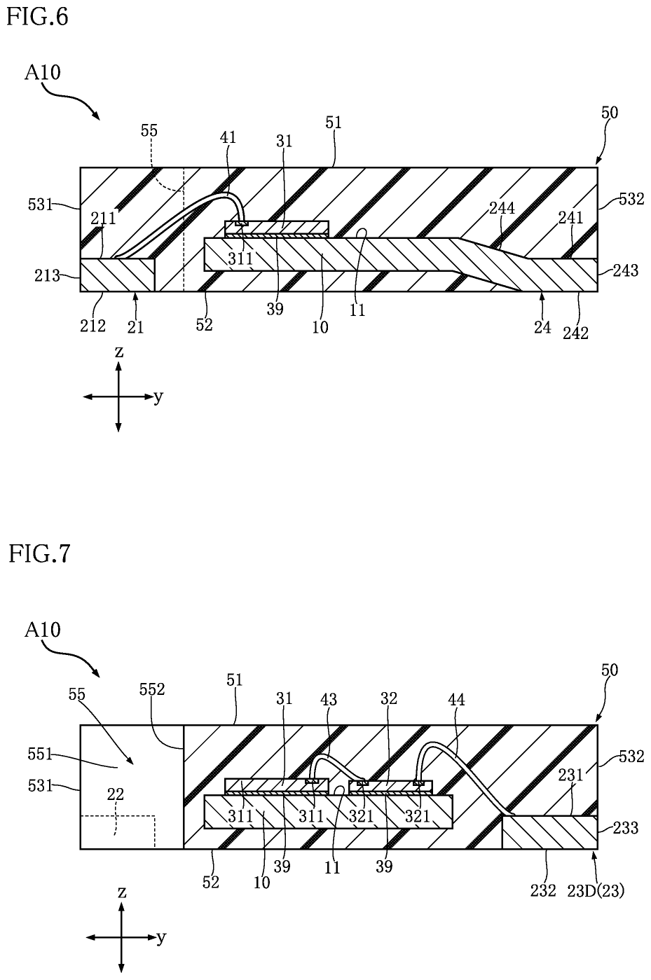

As shown in FIGS. 6 to 8, the sealing resin 50 covers the die pad 10, the first semiconductor element 31, the second semiconductor element 32, and a portion of each of the first lead 21, the second lead 22, the third leads 23, and the two fourth leads 24. The sealing resin 50 is electrically insulating. The sealing resin 50 includes a black epoxy resin, for example. As shown in FIGS. 1 and 3, the sealing resin 50 has a top surface 51, a bottom surface 52, a first side surface 531, and a second side surface 532.

As shown in FIGS. 6 to 8, the bottom surface 52 faces one side in the third direction z. The top surface 51 faces away from the bottom surface 52 in the third direction z.

As shown in FIGS. 6 and 7, the first side surface 531 faces one side in the second direction y. The second side surface 532 faces away from the first side surface 531 in the second direction y. The second side surface 532 is located opposite to the first side surface 531 in the second direction y with respect to the die pad 10. The first side surface 531 and the second side surface 532 are connected to the bottom surface 52. In the semiconductor device A10, the first side surface 531 and the second side surface 532 are also connected to the top surface 51.

As shown in FIG. 2, the die pad 10 is located between the first and second leads 21 and 22 and the third leads 23 in the second direction y. The die pad 10 contains a metallic element, which may be copper (Cu), for example. The die pad 10, the first lead 21, the second lead 22, the third leads 23, and the two fourth leads 24 can be obtained from a single lead frame. As shown in FIGS. 1 and 2, the die pad 10 has a mounting surface 11. The mounting surface 11 faces the same side as the top surface 51 of the sealing resin 50 in the third direction z. As shown in FIGS. 6 and 7, the die pad 10 is spaced apart from the bottom surface 52 of the sealing resin 50.

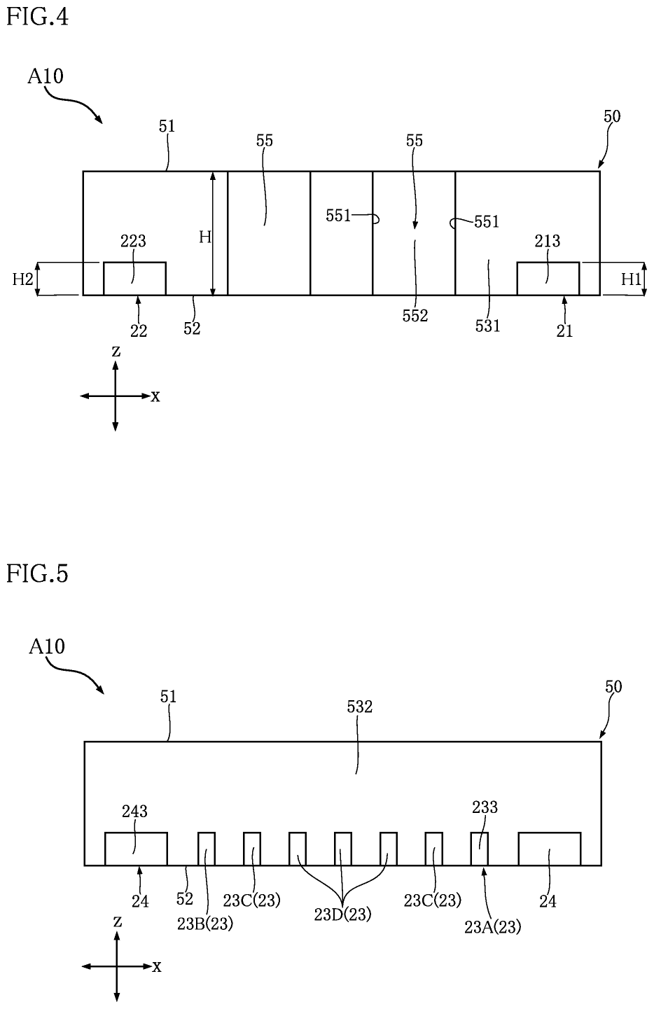

As shown in FIG. 2, the first lead 21 is located on one side of the die pad 10 in the second direction y. As shown in FIGS. 2, 3, and 6, the first lead 21 has a first obverse surface 211, a first reverse surface 212, and a first end surface 213. The first obverse surface 211 faces the same side as the top surface 51 of the sealing resin 50 in the third direction z. In the semiconductor device A10, the first obverse surface 211 is covered with the sealing resin 50. The first reverse surface 212 faces away from the first obverse surface 211 in the third direction z. The first reverse surface 212 is exposed from the bottom surface 52 of the sealing resin 50. The first end surface 213 faces the same side as the first side surface 531 of the sealing resin 50 in the second direction y. As shown in FIG. 4, the first end surface 213 is exposed from the first side surface 531.

As shown in FIG. 2, the second lead 22 is located on the same side as the first lead 21 in the second direction y with respect to the die pad 10. The second lead 22 is spaced apart from the first lead 21 in the first direction x. As shown in FIGS. 2 and 3, the second lead 22 has a second obverse surface 221, a second reverse surface 222, and a second end surface 223. The second obverse surface 221 faces the same side as the top surface 51 of the sealing resin 50 in the third direction z. In the semiconductor device A10, the second obverse surface 221 is covered with the sealing resin 50. The second reverse surface 222 faces away from the second obverse surface 221 in the third direction z. The second reverse surface 222 is exposed from the bottom surface 52 of the sealing resin 50. The second end surface 223 faces the same side as the first side surface 531 of the sealing resin 50 in the second direction y. As shown in FIG. 4, the second end surface 223 is exposed from the first side surface 531.

As shown in FIG. 2, the third leads 23 are located opposite to the first lead 21 and the second lead 22 in the second direction y with respect to the die pad 10. The third leads 23 are arranged next to each other in the first direction x. The spacing between each two third leads 23 next to each other in the first direction x is smaller than the spacing between the first lead 21 and the second lead 22. The third leads 23 include a first terminal 23A, a second terminal 23B, two third terminals 23C, and a plurality of fourth terminals 23D.

As shown in FIGS. 2, 3, and 7, each third lead 23 has a third obverse surface 231, a third reverse surface 232, and a third end surface 233. The third obverse surface 231 faces the same side as the top surface 51 of the sealing resin 50 in the third direction z. In the semiconductor device A10, the third obverse surface 231 is covered with the sealing resin 50. The third reverse surface 232 faces away from the third obverse surface 231 in the third direction z. The third reverse surface 232 is exposed from the bottom surface 52 of the sealing resin 50. The third end surface 233 faces the same side as the second side surface 532 of the sealing resin 50 in the second direction y. As shown in FIG. 5, the third end surface 233 is exposed from the second side surface 532.

As shown in FIG. 2, the two fourth leads 24 are located on the same side as the third leads 23 in the second direction y with respect to the die pad 10. The two fourth leads 24 are located one on each side in the first direction x with respect to the third leads 23. The two fourth leads 24 are connected to the die pad 10. The die pad 10 are supported by the two fourth leads 24.

As shown in FIGS. 2, 3, and 7, each of the two fourth leads 24 has a fourth obverse surface 241, a fourth reverse surface 242, a fourth end surface 243, and a connecting surface 244. The fourth obverse surface 241 faces the same side as the top surface 51 of the sealing resin 50 in the third direction z. In the semiconductor device A10, the fourth obverse surface 241 is covered with the sealing resin 50. The fourth reverse surface 242 faces away from the fourth obverse surface 241 in the third direction z. The fourth reverse surface 242 is exposed from the bottom surface 52 of the sealing resin 50. The fourth end surface 243 faces the same side as the second side surface 532 of the sealing resin 50 in the second direction y. As shown in FIG. 5, the fourth end surface 243 is exposed from the second side surface 532. The connecting surface 244 connects the fourth obverse surface 241 and the mounting surface 11 of the die pad 10. The connecting surface 244 is inclined relative to the fourth obverse surface 241 and the mounting surface 11. The connecting surface 244 is covered with the sealing resin 50.

As shown in FIGS. 2 and 7, the first semiconductor element 31 and the second semiconductor element 32 are mounted on the mounting surface 11 of the die pad 10. Each of the first semiconductor element 31 and the second semiconductor element 32 is an integrated circuit (IC). The second semiconductor element 32 is located between the first semiconductor element 31 and the plurality of third leads 23 in the second direction y. As shown in FIG. 7, the first semiconductor element 31 and the second semiconductor element 32 are bonded to the mounting surface 11 via a bonding layer 39. In one example, the bonding layer 39 is made of a paste composed mostly of an epoxy resin containing silver (called an Ag paste).

As shown in FIG. 2, the first semiconductor element 31 includes a plurality of first electrodes 311. The first electrodes 311 are electrically connected to the circuit formed in the first semiconductor element 31. As shown in FIG. 2, the second semiconductor element 32 includes a plurality of second electrodes 321. The second electrodes 321 are electrically connected to the circuit formed in the second semiconductor element 32.

As shown in FIG. 2, the semiconductor device A10 additionally includes two first wires 41, a plurality of second wires 42, a plurality of third wires 43, and a plurality of fourth wires 44. The wires contain gold (Au), for example. The wires are covered with the sealing resin 50.

As shown in FIG. 2, the two first wires 41 are separately bonded to two first electrodes 311 of the first semiconductor element 31 and to the first obverse surface 211 of the first lead 21 and the second obverse surface 221 of the second lead 22. This electrically connects each of the first lead 21 and the second lead 22 to the first semiconductor element 31.

As shown in FIG. 2, the second wires 42 are separately bonded to two first electrodes 311 of the first semiconductor element 31 and to the third obverse surface 231 of the first terminal 23A and the third obverse surface 231 of the second terminal 23B. This electrically connects the first semiconductor element 31 to the first terminal 23A and the second terminal 23B.

As shown in FIG. 2, the third wires 43 are separately bonded to a plurality of first electrodes 311 of the first semiconductor element 31 and a plurality of second electrodes 321 of the second semiconductor element 32. This electrically connects the second semiconductor element 32 to the first semiconductor element 31.

As shown in FIG. 2, the fourth wires 44 are separately bonded to a plurality of second electrodes 321 of the second semiconductor element 32 and to the third obverse surfaces 231 of the two third terminals 23C and the third obverse surfaces 231 of the fourth terminals 23D. This electrically connects the second semiconductor element 32 to the two third terminals 23C and the plurality of fourth terminals 23D.

As shown in FIGS. 1, 3, and 4, the sealing resin 50 is formed with a plurality of recesses 55. The recesses 55 are located between the first lead 21 and the second lead 22 in the first direction x. As shown in FIGS. 6 and 7, the recesses 55 overlap with the first lead 21 and the second lead 22 as viewed in the first direction x. In the semiconductor device A10, the recesses 55 are recessed from the first side surface 531 of the sealing resin 50.

As shown in FIGS. 3 and 4, each recess 55 has a pair of inside surfaces 551 and an intermediate surface 552. The pair of inside surfaces 551 face each other in the first direction x. The pair of inside surfaces 551 are connected to the bottom surface 52 and the top surface 51 of the sealing resin 50. The intermediate surface 552 is located between the pair of inside surfaces 551 in the first direction x. In the semiconductor device A10, the intermediate surface 552 faces the same side as the first side surface 531 of the sealing resin 50 in the second direction y.

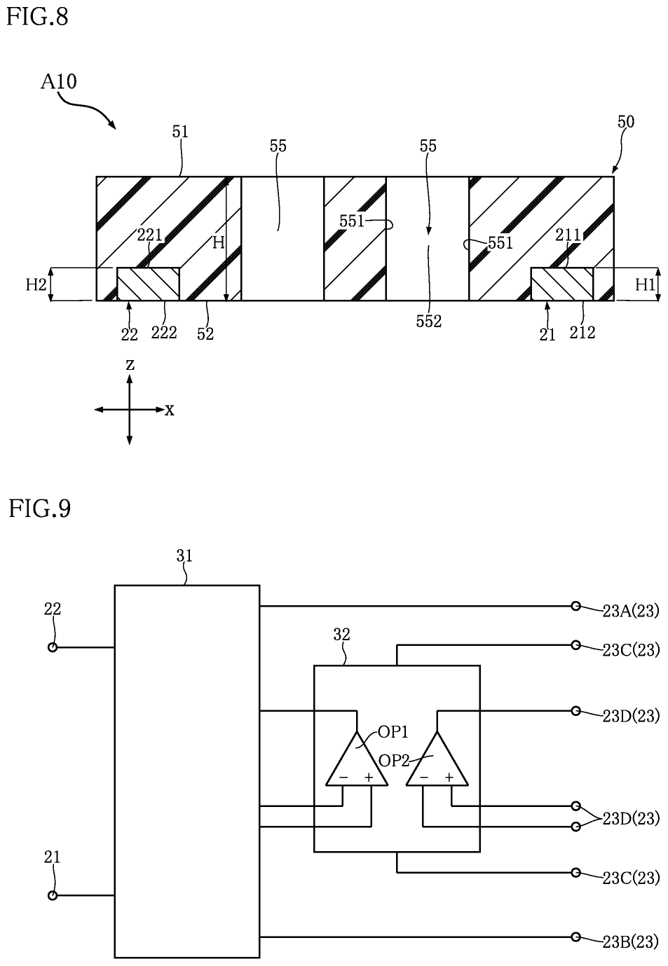

As shown in FIG. 3, each inside surface 551 has a length L in the second direction y, and the first lead 21 and the second lead 22 respectively have lengths L1 and L2 in the second direction y, where the length L is greater than the lengths L1 and L2. As shown in FIG. 8, each inside surface 551 has a length H in the third direction z, and the first lead 21 and the second lead 22 respectively have lengths H1 and H2, where the length H is greater than the lengths H1 and H2.

With reference to FIG. 9, the following describes the circuit arrangement of the semiconductor device A10.

In the first semiconductor element 31, a step-down circuit is formed. The step-down circuit includes a plurality of resistive elements. The first lead 21 and the second lead 22 are connected to a battery (not shown) that is a target to be monitored. The first lead 21 is a positive electrode, and the second lead 22 is a negative electrode. The voltage of the battery applied between the first lead 21 and the second lead 22 is converted by the step-down circuit of the first semiconductor element 31 into a weak electrical signal.

As shown in FIG. 9, the second semiconductor element 32 includes two operational amplifiers OP1 and OP2. In a different example, however, the second semiconductor element 32 may not include the operational amplifier OP2. The operational amplifier OP1 amplifies the week electrical signal converted by the first semiconductor element 31 and outputs the amplified signal to the first terminal 23A via the first semiconductor element 31. This enables the voltage of the battery to be monitored.

The second terminal 23B is the ground of the first semiconductor element 31. The two third terminals 23C are connected to a power supply for driving the second semiconductor element 32. The fourth terminals 23D are electrically connected to the operational amplifier OP2. The operational amplifier OP2 receives an electrical signal generated by a control circuit (not shown) on the basis of the electrical signal outputted from the first terminal 23A. In this way, high-frequency noise present in the electrical signal outputted from the first terminal 23A is removed by the operational amplifier OP2 to enable more accurate monitoring of the battery voltage.

### Variation of First Embodiment

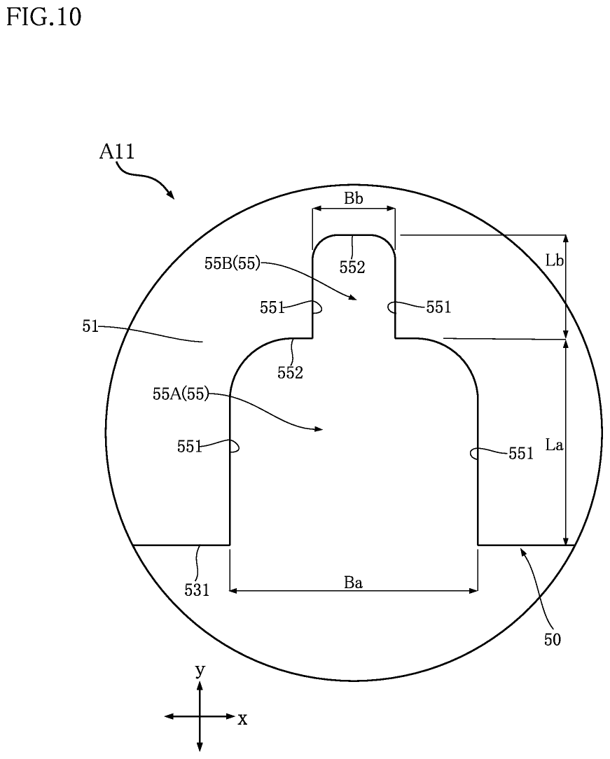

Next, with reference to FIG. 10, the following describes a semiconductor device A11 that is a variation of the semiconductor device A10.

As shown in FIG. 10, in the semiconductor device A11, each of the plurality of recesses 55 is formed with a first recess 55A and a second recess 55B. The first recess 55A is recessed from the first side surface 531 of the sealing resin 50. The second recess 55B is recessed from the intermediate surface 552 of the first recess 55A. The second recess 55B is connected to the first recess 55A.

As shown in FIG. 10, the first recess 55A has a length Ba in the first direction x, and the second recess 55B as a length Bb in the first direction x, where the length Bb is smaller than the length Ba. In addition, the first recess 55A has a length La in the second direction y, and the second recess 55B has a length Lb in the second direction y, where the length Lb is smaller than the length La.

The following describes the operation and effect of the semiconductor device A10.

The semiconductor device A10 includes the sealing resin 50 that covers the first semiconductor element 31, a portion of the first lead 21, and a portion of the second lead 22. The second lead 22 is spaced apart from the first lead 21 in the first direction x. The sealing resin 50 is formed with the recesses 55 located between the first lead 21 and the second lead 22 in the first direction x. As viewed in the first direction x, the recesses 55 overlap with the first lead 21 and the second lead 22. With this configuration, the sealing resin 50 can provide a longer creepage distance (the distance along the surface of the sealing resin 50) from the first lead 21 to the second lead 22. This allows the spacing between the first lead 21 and the second lead 22 to be reduced in the first direction x. Nevertheless, electric discharge from the first lead 21 to the second lead 22 is suppressed even when the voltage applied is relatively higher at the first lead 21 than at the second lead 22. The semiconductor device A10 can therefore be made compact and yet capable of suppressing the discharge between the leads.

Each recess 55 has a pair of inside surfaces 551 facing each other in the first direction x. With this configuration, the sealing resin 50 can provide a longer creepage distance from the first lead 21 to the second lead 22.

The length L of each inside surface 551 in the second direction y is greater than the lengths L1 and L2 respectively of the first lead 21 and the second lead 22 in the second direction y (see FIG. 3). In addition, the length H of each inside surface 551 in the third direction z is greater than the lengths H1 and H2 respectively of the first lead 21 and the second lead 22 in the third direction z (see FIG. 8). As viewed in first direction x, the first lead 21 and the second lead 22 are contained within the outline of the recesses 55. This makes is possible to more efficiently suppress the discharge between the first lead 21 and the second lead 22.

Each recess 55 has an intermediate surface 552 located between the pair of inside surfaces 551 in the first direction x. The intermediate surface 552 faces in the second direction y. With this configuration, the sealing resin 50 can provide a longer creepage distance from the first lead 21 to the second lead 22.

As shown in FIG. 10, the semiconductor device A11 has the recesses 55 each of which is formed with a first recess 55A and a second recess 55B. The length Bb of the second recess 55B in the first direction x is smaller than the length Ba of the first recess 55A in the first direction x. In addition, the length Lb of the second recess 55B in the second direction y is smaller than the length La of the first recess 55A in the second direction y. With this configuration, the sealing resin 50 can provide a longer creepage distance from the first lead 21 to the second lead 22, and the volume of the recesses 55 can be reduced.

Each recess 55 includes a plurality of regions along the first direction x. With this configuration, the sealing resin 50 can more efficiently increase the creepage distance from the first lead 21 to the second lead 22.

The first lead 21 and the second lead 22 are exposed from the first side surface 531 of the sealing resin 50. In the process of mounting the semiconductor device A10 to a wiring board, this configuration helps solder fillet to form at the portions of the first lead 21 and the second lead 22 exposed from the first side surface 531. This can consequently increase the bonding strength of the semiconductor device A10 to the wiring board.

### Second Embodiment

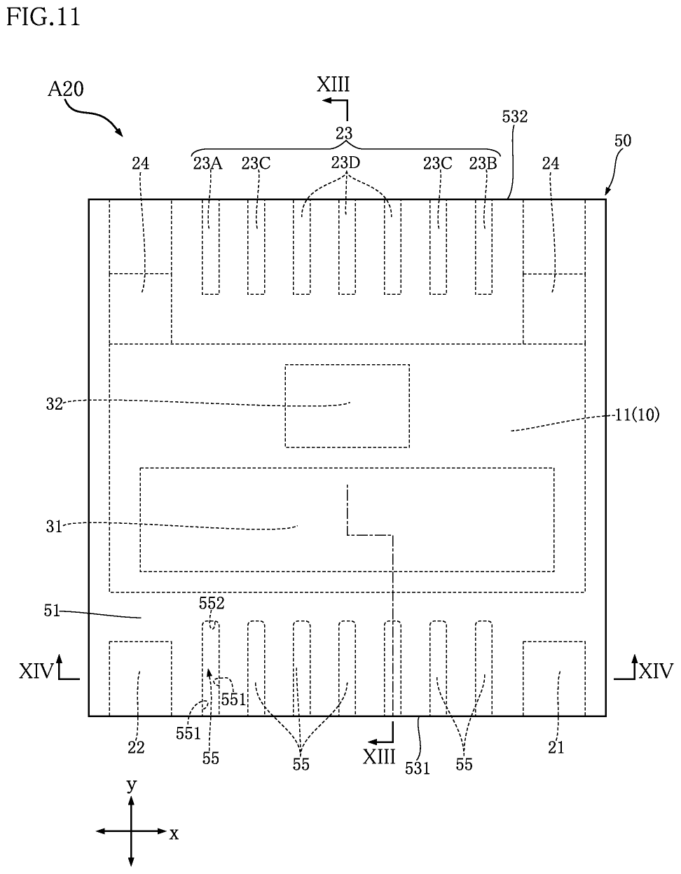

With reference to FIGS. 11 to 14, the following describes a semiconductor device A20 according to a second embodiment of the present disclosure. In the figures, the elements identical or similar to those of the semiconductor device A10 described above are denoted by the same reference numerals, and descriptions of such elements are omitted to avoid redundancy. FIG. 11 shows a line XIII-XIII with a dot-dash line.

The semiconductor device A20 includes a sealing resin 50 formed with a plurality of recesses 55 different from those of the semiconductor device A10.

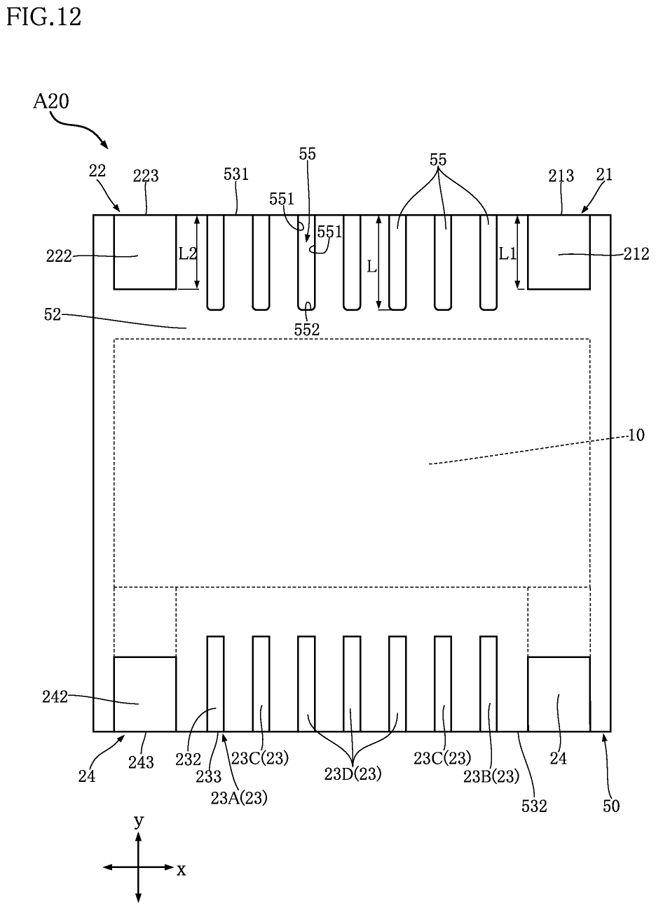

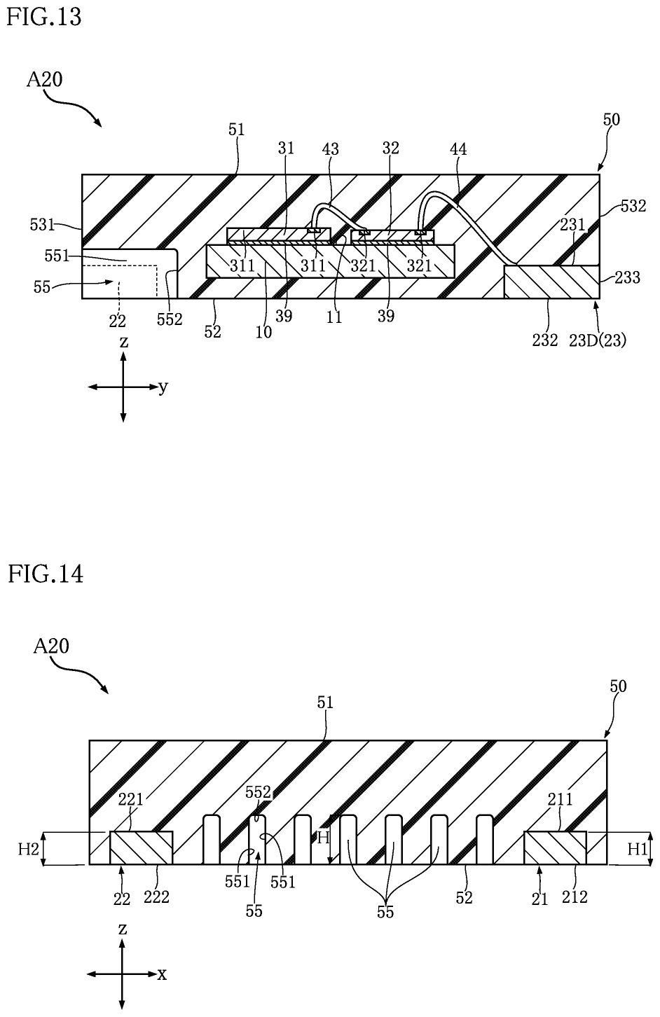

As shown in FIGS. 13 and 14, the recesses 55 are recessed from the bottom surface 52 of the sealing resin 50. As shown in FIGS. 11 and 12, the recesses 55 are grooves extending in the second direction y. As shown in FIGS. 12 and 13, each recess 55 has a pair of inside surfaces 551 connected to the first side surface 531 of the sealing resin 50. Each recess 55 also has an intermediate surface 552 facing the same side as the bottom surface 52 in the third direction z.

In the semiconductor device A20 as shown in FIGS. 11 to 13, the recesses 55 overlap with the first lead 21 and the second lead 22 as viewed in the first direction x. As shown in FIG. 12, each inside surface 551 has a length L in the second direction y, and the first lead 21 and the second lead 22 respectively have lengths L1 and L2 in the second direction y, where the length L is greater the lengths L1 and L2. As shown in FIG. 14, each inside surface 551 has a length H in the third direction z, and the first lead 21 and the second lead 22 respectively have lengths H1 and H2 in the third direction z, where the length H is greater than the lengths H1 and H2.

The recesses 55 of the semiconductor device A20 are smaller in length in the first direction x than those of the semiconductor device A10.

The following describes the operation and effect of the semiconductor device A20.

The semiconductor device A20 includes the sealing resin 50 that covers the first semiconductor element 31, a portion of the first lead 21, and a portion of the second lead 22. The second lead 22 is spaced apart from the first lead 21 in the first direction x. The sealing resin 50 has the recesses 55 formed between the first lead 21 and the second lead 22 in the first direction x. As viewed in the first direction x, the recesses 55 overlap with the first lead 21 and the second lead 22. The semiconductor device A20 can therefore be made compact and yet capable of suppressing the discharge between the leads. The semiconductor device A20 has features common with the semiconductor device A10 and thus achieves the same operation and effect as those achieved by the corresponding features of the semiconductor device A10.

### Third Embodiment

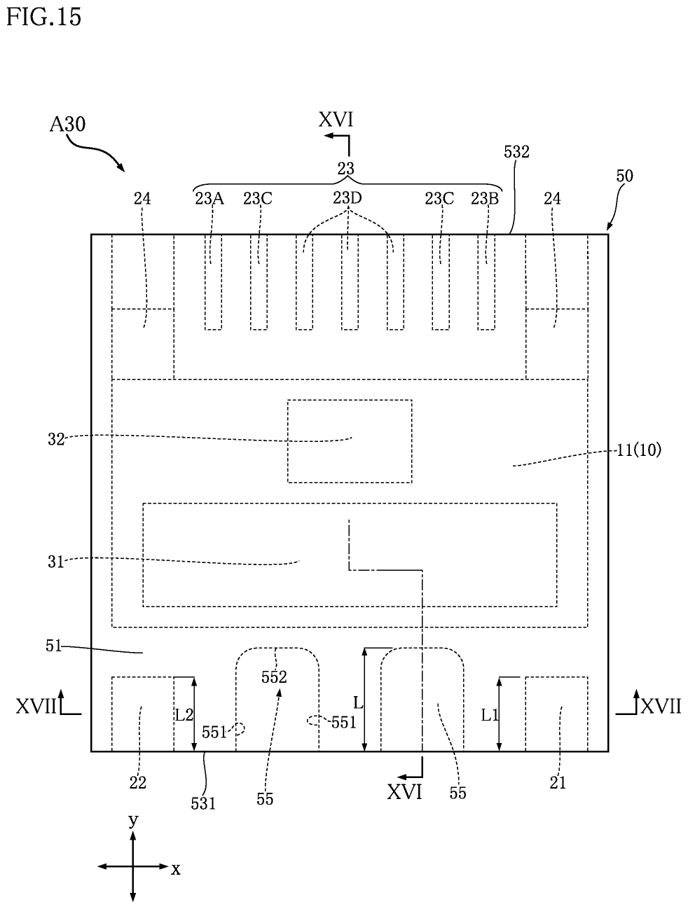

With reference to FIGS. 15 to 17, the following describes a semiconductor device A30 according to a third embodiment of the present disclosure. In the figures, the elements identical or similar to those of the semiconductor device A10 described above are denoted by the same reference numerals, and descriptions of such elements are omitted to avoid redundancy. FIG. 15 shows a line XVI-XVI with a dot-dash line.

The semiconductor device A30 includes a sealing resin 50 formed with a plurality of recesses 55 different from those of the semiconductor device A10.

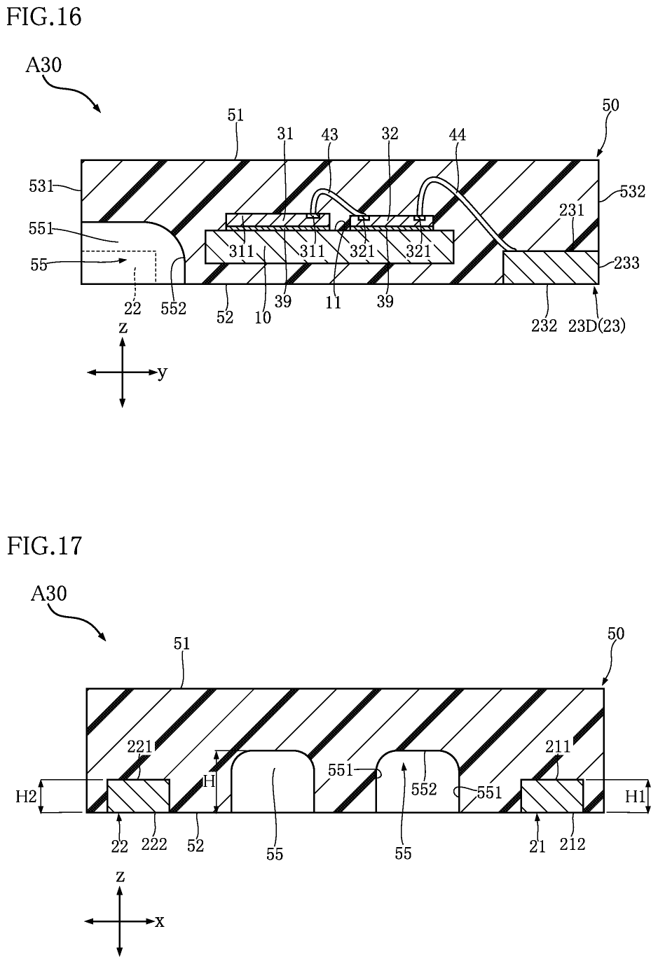

As shown in FIGS. 16 and 17, the recesses 55 are recessed from the first side surface 531 and the bottom surface 52 of the sealing resin 50. Each recess 55 has a pair of inside surfaces 551 connected to the first side surface 531 and the bottom surface 52. Each recess 55 also has an intermediate surface 552 facing the same side as the first side surface 531 in the second direction y and the same side as the bottom surface 52 in the third direction z.

In the semiconductor device A30 as shown in FIGS. 15 and 16, the recesses 55 overlap with the first lead 21 and the second lead 22 as viewed in the first direction x. As shown in FIG. 15, each inside surface 551 has a length L in the second direction y, and the first lead 21 and the second lead 22 respectively have lengths L1 and L2 in the second direction y, where the length L is greater the lengths L1 and L2. As shown in FIG. 17, each inside surface 551 has a length H in the third direction z, and the first lead 21 and the second lead 22 respectively have lengths H1 and H2 in the third direction z, where the length H is greater than the lengths H1 and H2.

The following describes the operation and effect of the semiconductor device A30.

The semiconductor device A30 includes the sealing resin 50 that covers the first semiconductor element 31, a portion of the first lead 21, and a portion of the second lead 22. The second lead 22 is spaced apart from the first lead 21 in the first direction x. The sealing resin 50 has the recesses 55 formed between the first lead 21 and the second lead 22 in the first direction x. As viewed in the first direction x, the recesses 55 overlap with the first lead 21 and the second lead 22. The semiconductor device A30 can therefore be made compact and yet capable of suppressing the discharge between the leads. In addition, the semiconductor device A30 has features common with the semiconductor device A10 and thus achieves the same operation and effect as those achieved by the corresponding features of the semiconductor device A10.

### Fourth Embodiment

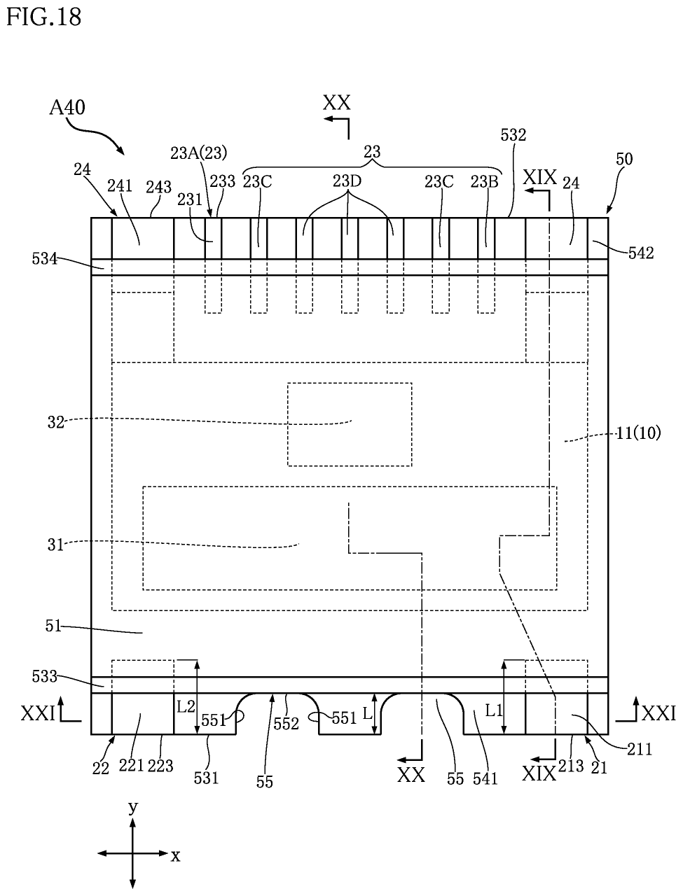

With reference to FIGS. 18 to 21, the following describes a semiconductor device A40 according to a fourth embodiment of the present disclosure. In the figures, the elements identical or similar to those of the semiconductor device A10 described above are denoted by the same reference numerals, and descriptions of such elements are omitted to avoid redundancy. FIG. 18 show lines XIX-XIX and XX-XX with dot-dash lines.

The semiconductor device A40 includes a sealing resin 50 different from that of the semiconductor device A10.

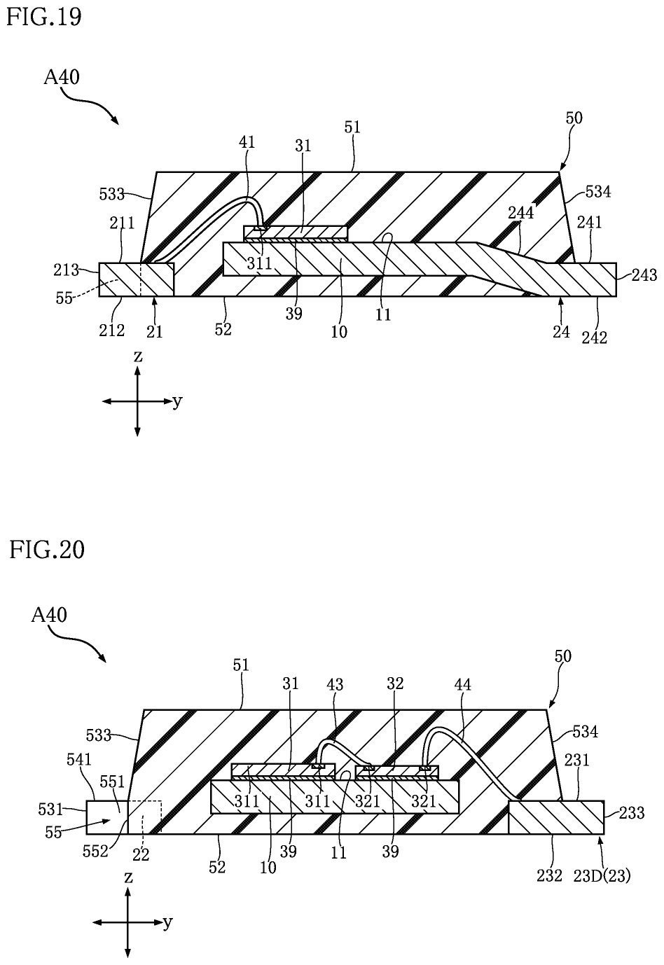

As shown in FIG. 18, the sealing resin 50 additionally has a third side surface 533 and a fourth side surface 534. The third side surface 533 and the fourth side surface 534 face away from each other in the second direction y and are connected to the top surface 51 of the sealing resin 50. The third side surface 533 is located between the top surface 51 and the first side surface 531 in the second direction y. The fourth side surface 534 is located between the top surface 51 and the second side surface 532 in the second direction y. As shown in FIGS. 19 and 20, the third side surface 533 and the fourth side surface 534 are inclined relative to the top surface 51.

As shown in FIG. 18, the sealing resin 50 additionally has a first overhang surface 541 and a second overhanging surface 542. The first overhang surface 541 and the second overhanging surface 542 face the same side as the top surface 51 of the sealing resin 50 in the third direction z. The first overhang surface 541 and the second overhanging surface 542 extend in the first direction x.

As shown in FIGS. 18 and 20, the first overhang surface 541 is located between the first side surface 531 and the third side surface 533 of the sealing resin 50 in both the second direction y and the third direction z. The first overhang surface 541 is connected to the first side surface 531 and the third side surface 533. The first obverse surface 211 of the first lead 21 and the second obverse surface 221 of the second lead 22 are partly exposed from the first overhang surface 541.

As shown in FIG. 18, the second overhanging surface 542 is located between the second side surface 532 and the fourth side surface 534 of the sealing resin 50 in both the second direction y and the third direction z. The second overhanging surface 542 is connected to the second side surface 532 and the fourth side surface 534. The third obverse surface 231 of each third lead 23 and the fourth obverse surface 241 of each of the two fourth leads 24 are partly exposed from the second overhanging surface 542.

As shown in FIGS. 18 and 20, in the semiconductor device A40, the recesses 55 are recessed from the first side surface 531 of the sealing resin 50. Each recess 55 has a pair of inside surfaces 551 each of which is connected to the bottom surface 52 and the first overhanging surface 541 of the sealing resin 50. Each recess 55 also has an intermediate surface 552 facing the same side as the first side surface 531 in the second direction y and connected to the bottom surface 52 and the first overhang surface 541.

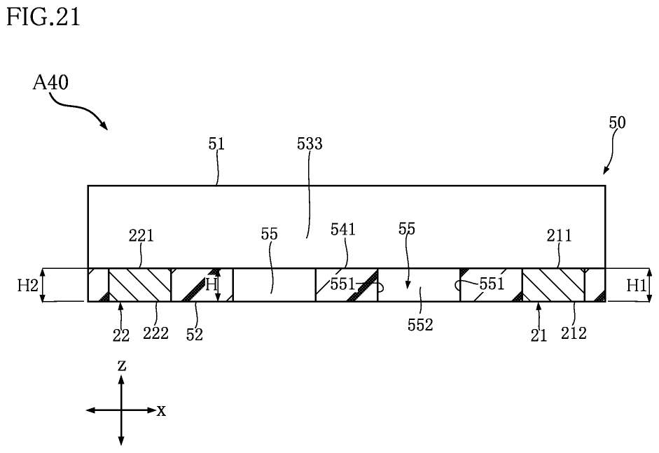

As shown in FIGS. 18 to 20, in the semiconductor device A40, the recesses 55 overlap with the first lead 21 and the second lead 22 as viewed in the first direction x. As shown in FIG. 18, each inside surface 551 has a length L in the second direction y, and the first lead 21 and the second lead 22 respectively have lengths L1 and L2 in the second direction y, where the length L is smaller the lengths L1 and L2. As shown in FIG. 21, each inside surface 551 has a length H in the third direction z, and the first lead 21 and the second lead 22 respectively have lengths H1 and H2 in the third direction z, where the length H is equal to the lengths H1 and H2.

The following describes the operation and effect of the semiconductor device A40.

The semiconductor device A40 includes the sealing resin 50 that covers the first semiconductor element 31, a portion of the first lead 21, and a portion of the second lead 22. The second lead 22 is spaced apart from the first lead 21 in the first direction x. The sealing resin 50 has the recesses 55 formed between the first lead 21 and the second lead 22 in the first direction x. As viewed in the first direction x, the recesses 55 overlap with the first lead 21 and the second lead 22. The semiconductor device A40 can therefore be made compact and yet capable of suppressing the discharge between the leads. In addition, the semiconductor device A40 has features common with the semiconductor device A10 and thus achieves the same operation and effect as those achieved by the corresponding features of the semiconductor device A10.

### Fifth Embodiment

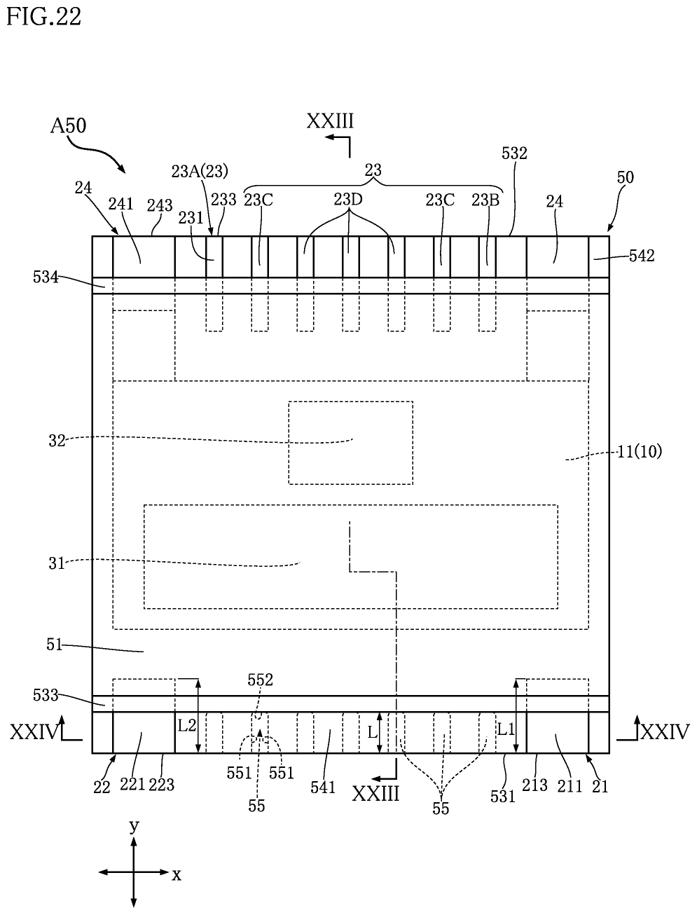

With reference to FIGS. 22 to 24, the following describes a semiconductor device A50 according to a fifth embodiment of the present disclosure. In the figures, the elements identical or similar to those of the semiconductor device A10 described above are denoted by the same reference numerals, and descriptions of such elements are omitted to avoid redundancy. FIG. 22 shows a line XXIII-XXIII with a dot-dash line.

The semiconductor device A50 includes a sealing resin 50 formed with a plurality of recesses 55 different from those of the semiconductor device A40.

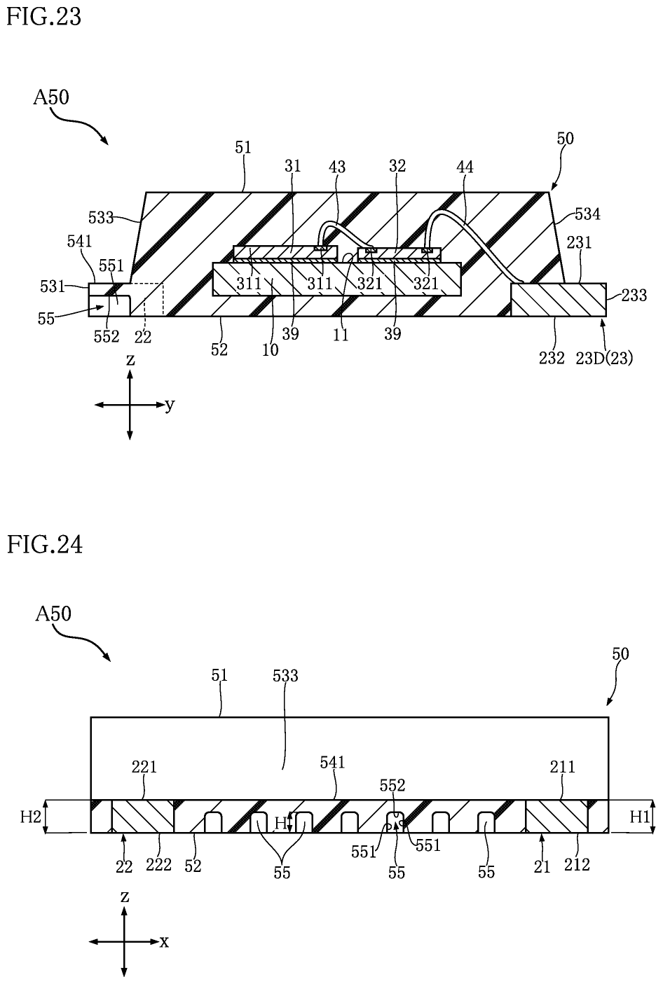

As shown in FIGS. 23 and 24, the recesses 55 are recessed from the bottom surface 52 of the sealing resin 50. As shown in FIG. 22, the recesses 55 are grooves extending in the second direction y. As shown in FIGS. 22 and 23, each recess 55 has a pair of inside surfaces 551 connected to the first side surface 531 of the sealing resin 50. Each recess 55 also has an intermediate surface 552 facing the same side as the bottom surface 52 in the third direction z.

As shown in FIGS. 22 and 23, in the semiconductor device A50, the recesses 55 overlap with the first lead 21 and the second lead 22 as viewed in the first direction x. As shown in FIG. 22, each inside surface 551 has a length L in the second direction y, and the first lead 21 and the second lead 22 respectively have lengths L1 and L2 in the second direction y, where the length L is smaller the lengths L1 and L2. As shown in FIG. 24, each inside surface 551 has a length H in the third direction z, and the first lead 21 and the second lead 22 respectively have lengths H1 and H2 in the third direction z, where the length H is smaller than the lengths H1 and H2.

The recesses 55 of the semiconductor device A50 are smaller in length in the first direction x than those of the semiconductor device A40.

The following describes the operation and effect of the semiconductor device A50.

The semiconductor device A50 includes the sealing resin 50 that covers the first semiconductor element 31, a portion of the first lead 21, and a portion of the second lead 22. The second lead 22 is spaced apart from the first lead 21 in the first direction x. The sealing resin 50 has the recesses 55 formed between the first lead 21 and the second lead 22 in the first direction x. As viewed in the first direction x, the recesses 55 overlap with the first lead 21 and the second lead 22. The semiconductor device A50 can therefore be made compact and yet capable of suppressing the discharge between the leads. In addition, the semiconductor device A50 has features common with the semiconductor device A10 and thus achieves the same operation and effect as those achieved by the corresponding features of the semiconductor device A10.

### Sixth Embodiment

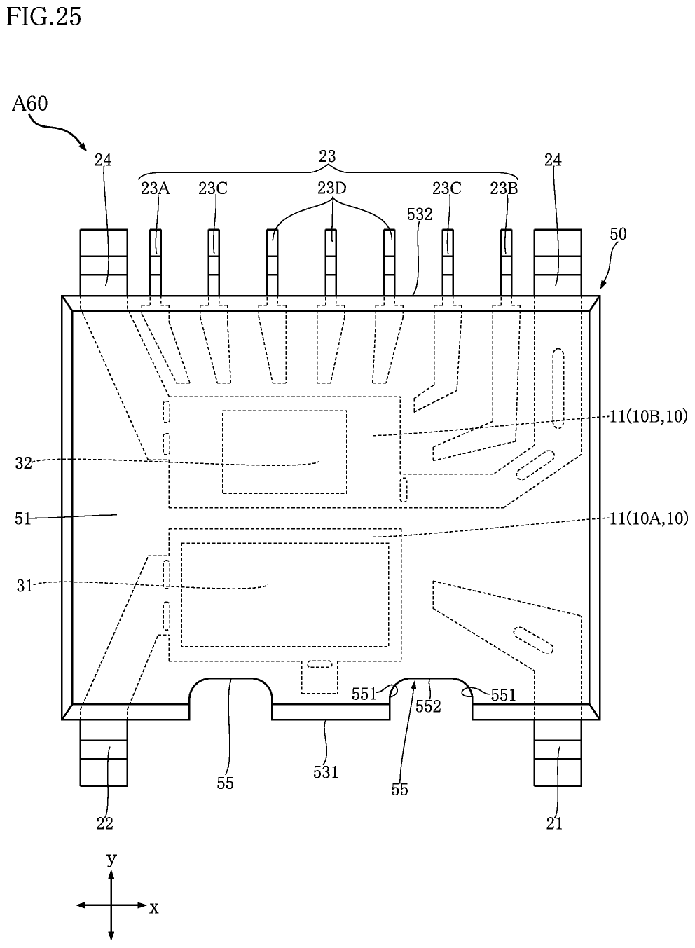

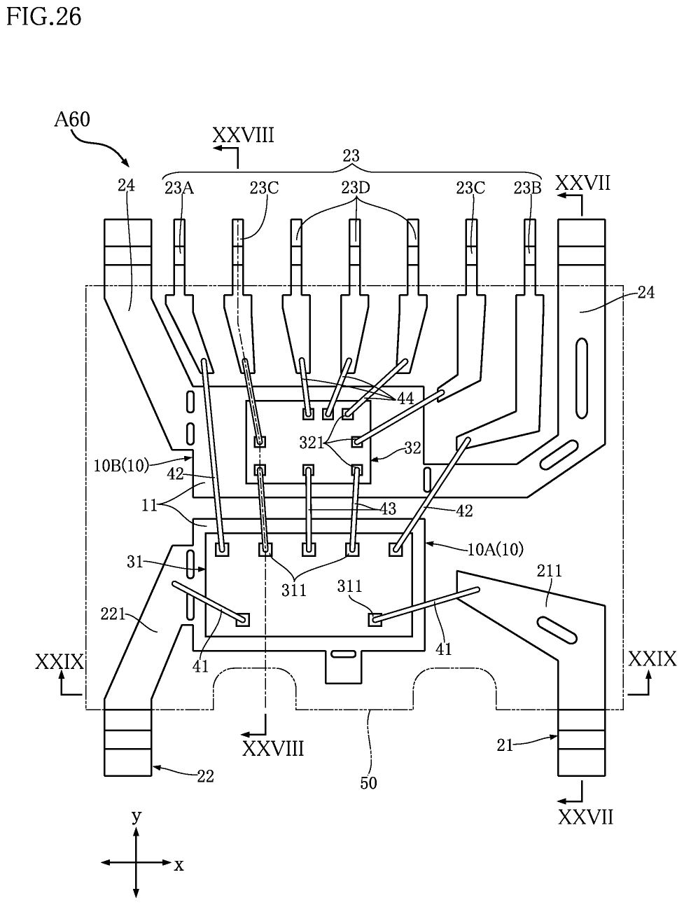

With reference to FIGS. 25 to 29, the following describes a semiconductor device A60 according to a sixth embodiment of the present disclosure. In the figures, the elements identical or similar to those of the semiconductor device A10 described above are denoted by the same reference numerals, and descriptions of such elements are omitted to avoid redundancy. For convenience, FIG. 26 shows the sealing resin 50 as transparent, with the outline of the sealing resin 50 indicated by imaginary lines (dot-dash lines). FIG. 26 shows a line XXVIII-XXVIII with a dot-dash line.

The semiconductor device A60 includes a die pad 10, a first lead 21, a second lead 22, a plurality of third leads 23, and two fourth leads 24 that are different from those of the semiconductor device A10. The semiconductor device A60 is packaged in a small outline package (SOP).

As shown in FIGS. 25, 26, and 28, the die pad 10 includes a first pad 10A and a second pad 10B. The second pad 10B is located between the first pad 10A and the plurality of third leads 23 in the second direction y. The first semiconductor element 31 is mounted on the mounting surface 11 of the first pad 10A. The second semiconductor element 32 is mounted on the mounting surface 11 of the second pad 10B. The second lead 22 is connected to the first pad 10A. The two fourth leads 24 are connected to the second pad 10B.

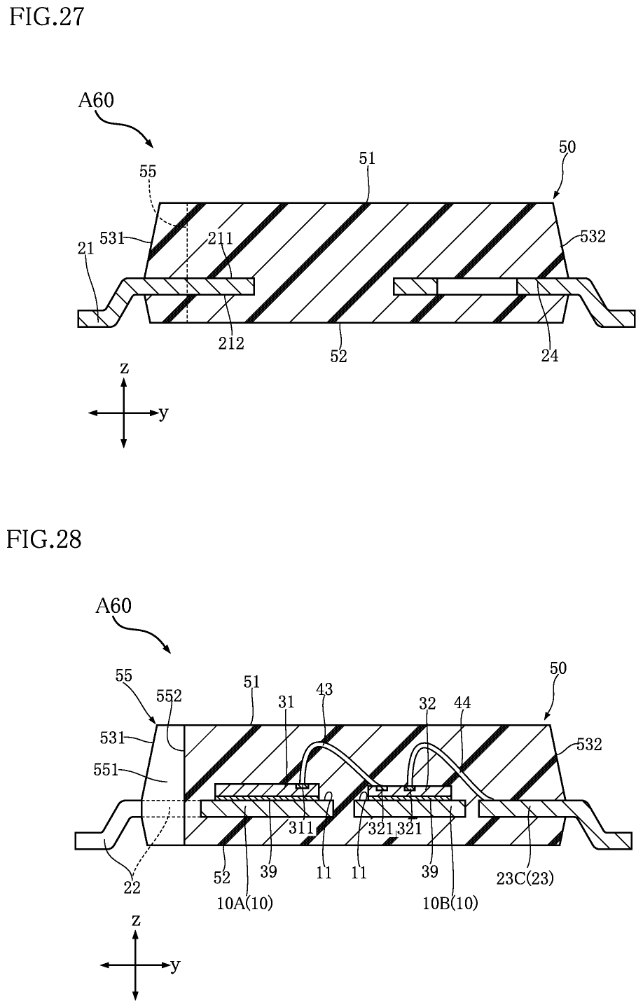

As shown in FIGS. 27 and 28, each of the first lead 21 and the second lead 22 are partly exposed from the first side surface 531 of the sealing resin 50. The exposed portion of each of the first lead 21 and the second lead 22 is bent toward the side closer to the bottom surface 52 of the sealing resin 50 in the third direction z. The first obverse surface 211 and the first reverse surface 212 of the first lead 21 as well as the second obverse surface 221 and the second reverse surface 222 of the second lead 22 are covered with the sealing resin 50.

As shown in FIGS. 27 and 28, the third leads 23 and the fourth leads 24 are exposed from the second side surface 532 of the sealing resin 50. The exposed portions of the third leads 23 and the fourth leads 24 are bent toward the bottom surface 52 of the sealing resin 50 in the third direction z.

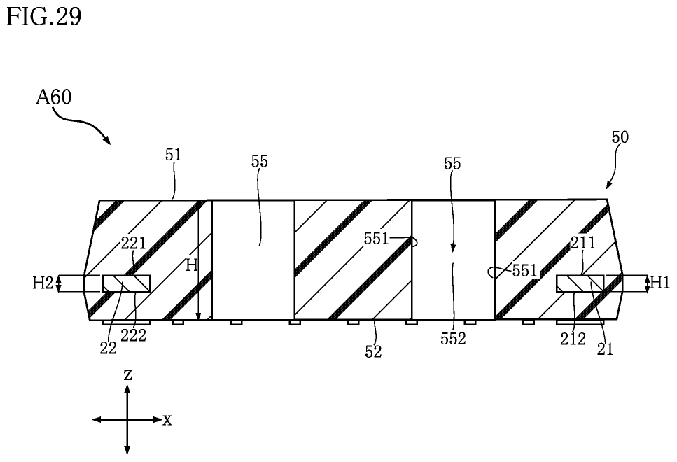

As shown in FIGS. 25, 27, and 28, in the semiconductor device A60, the recesses 55 overlap with the first lead 21 and the second lead 22 as viewed in the first direction x. As shown in FIG. 29, each inside surface 551 has a length H in the third direction z, and the first lead 21 and the second lead 22 respectively have lengths H1 and H2 in the third direction z, where the length H is greater than the lengths H1 and H2.

### Variation of Sixth Embodiment

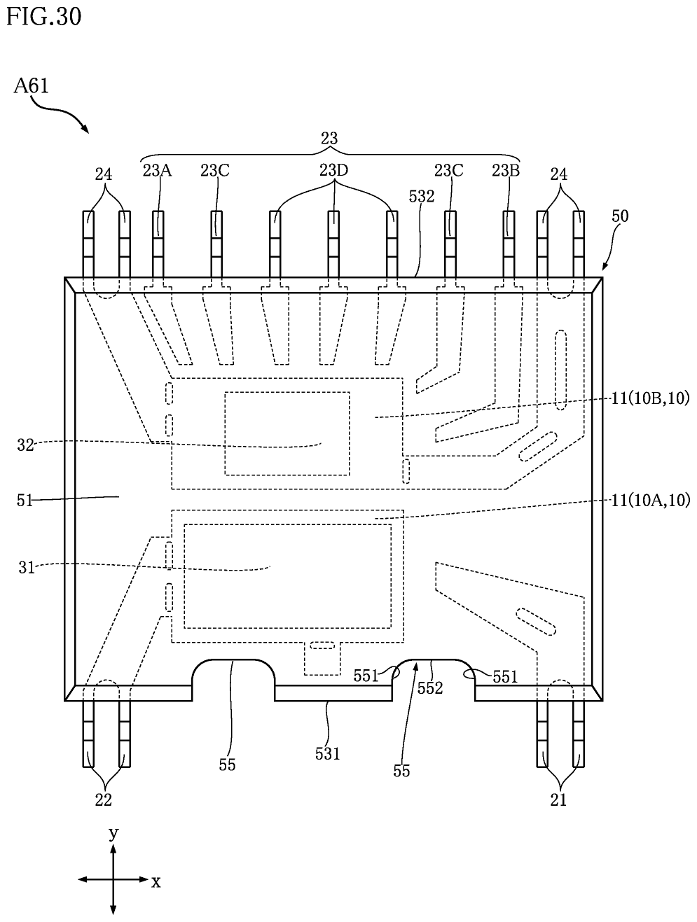

Next, with reference to FIG. 30, the following describes a semiconductor device A61 that is a variation of the semiconductor device A60.

As shown in FIG. 30, the semiconductor device A61 includes a first lead 21, a second lead 22, and two fourth leads 24, and each lead has bifurcated ends spaced apart in the first direction x and exposed from the sealing resin 50. Each bifurcated end of the first lead 21, the second lead 22, and the two fourth leads 24 is equal in length in the first direction x to the portion of each third lead 23 exposed from the sealing resin 50.

The following describes the operation and effect of the semiconductor device A60.

The semiconductor device A60 includes the sealing resin 50 that covers the first semiconductor element 31, a portion of the first lead 21, and a portion of the second lead 22. The second lead 22 is spaced apart from the first lead 21 in the first direction x. The sealing resin 50 has the recesses 55 formed between the first lead 21 and the second lead 22 in the first direction x. As viewed in the first direction x, the recesses 55 overlap with the first lead 21 and the second lead 22. The semiconductor device A60 can therefore be made compact and yet capable of suppressing the discharge between the leads. In addition, the semiconductor device A60 has features common with the semiconductor device A10 and thus achieves the same operation and effect as those achieved by the corresponding features of the semiconductor device A10.

### Seventh Embodiment

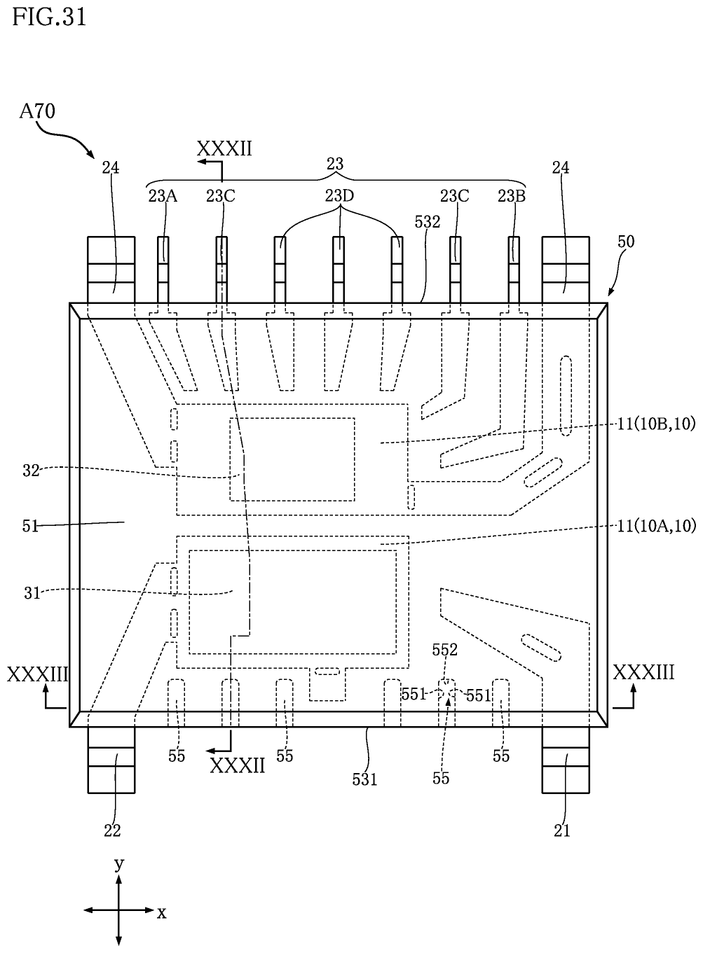

With reference to FIGS. 31 to 33, the following describes a semiconductor device A70 according to a seventh embodiment of the present disclosure. In the figures, the elements identical or similar to those of the semiconductor device A10 described above are denoted by the same reference numerals, and descriptions of such elements are omitted to avoid redundancy. FIG. 31 shows a line XXXII-XXXII with a dot-dash line.

The semiconductor device A70 includes a sealing resin 50 formed with a plurality of recesses 55 different from those of the semiconductor device A60 described above.

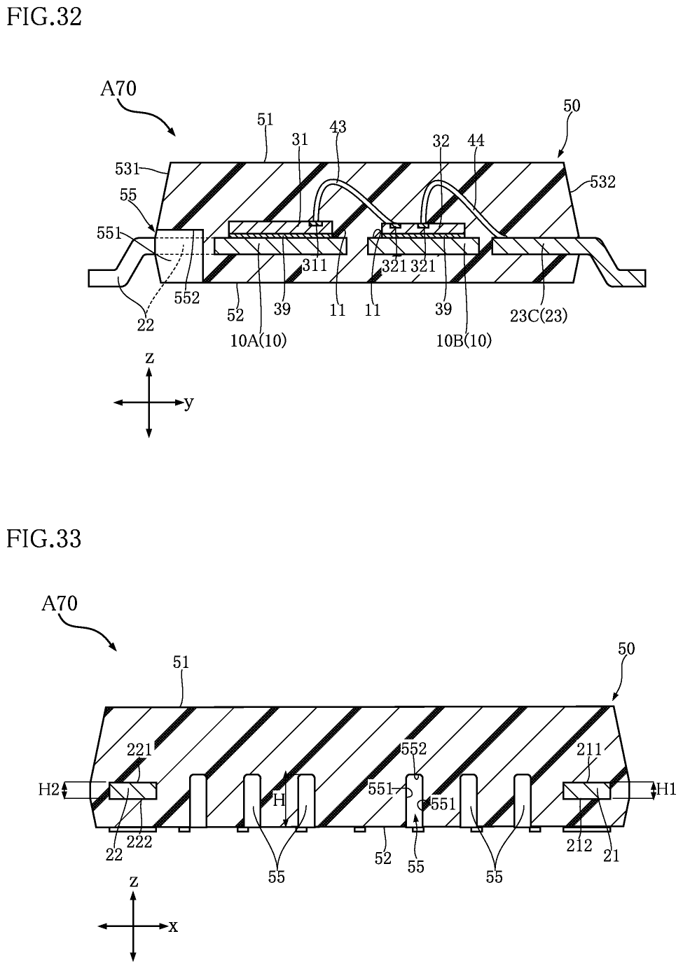

As shown in FIGS. 32 and 33, the recesses 55 are recessed from the bottom surface 52 of the sealing resin 50. As shown in FIG. 31, the recesses 55 are grooves extending in the second direction y. As shown in FIGS. 31 and 32, each recess 55 has a pair of inside surfaces 551 connected to the first side surface 531 of the sealing resin 50. Each recess 55 also has an intermediate surface 552 facing the same side as the bottom surface 52 in the third direction z.

As shown in FIGS. 31 and 32, in the semiconductor device A70, the recesses 55 overlap with the first lead 21 and the second lead 22 as viewed in the first direction x. As shown in FIG. 33, each inside surface 551 has a length H in the third direction z, and the first lead 21 and the second lead 22 respectively have lengths H1 and H2 in the third direction z, where the length H is greater than the lengths H1 and H2.

The recesses 55 of the semiconductor device A70 are smaller in length in the first direction x than those of the semiconductor device A60.

The following describes the operation and effect of the semiconductor device A70.

The semiconductor device A70 includes the sealing resin 50 that covers the first semiconductor element 31, a portion of the first lead 21, and a portion of the second lead 22. The second lead 22 is spaced apart from the first lead 21 in the first direction x. The sealing resin 50 has the recesses 55 formed between the first lead 21 and the second lead 22 in the first direction x. As viewed in the first direction x, the recesses 55 overlap with the first lead 21 and the second lead 22. The semiconductor device A70 can therefore be made compact and yet capable of suppressing the discharge between the leads. In addition, the semiconductor device A70 has features common with the semiconductor device A10 and thus achieves the same operation and effect as those achieved by the corresponding features of the semiconductor device A10.

The present disclosure is not limited to the embodiments described above. Various modifications in design may be made freely in the specific structure of each part according to the present disclosure.

The present disclosure includes embodiments described in the following clauses.

### Clause 1

A semiconductor device comprising:
a first semiconductor element formed with a step-down circuit;
a first lead electrically connected to the first semiconductor element;
a second lead electrically connected to the first semiconductor element and spaced apart from the first lead in a first direction; and
a sealing resin covering the first semiconductor element and a portion of each of the first lead and the second lead,
wherein the sealing resin includes a recess located between the first lead and the second lead in the first direction, and
the recess overlaps with the first lead and the second lead as viewed in the first direction.

### Clause 2

The semiconductor device according to Clause 1, wherein the sealing resin includes a first side surface facing in a second direction orthogonal to the first direction and a bottom surface facing in a third direction orthogonal to the first direction and the second direction, and
the recess is recessed from at least one of the first side surface and the bottom surface.

### Clause 3

The semiconductor device according to Clause 2, wherein the recess includes a pair of inside surfaces facing each other in the first direction.

### Clause 4

The semiconductor device according to Clause 3, wherein a length of each of the pair of inside surfaces in the second direction is greater than a length of each of the first lead and the second lead in the second direction.

### Clause 5

The semiconductor device according to Clause 3 or 4, wherein a length of each of the pair of inside surfaces in the third direction is greater than a length of each of the first lead and the second lead in the third direction.

### Clause 6

The semiconductor device according to any one of Clauses 3 to 5, wherein the recess is recessed from the first side surface, and
the pair of inside surfaces are connected to the bottom surface.

### Clause 7

The semiconductor device according to Clause 6, wherein the sealing resin includes a top surface facing away from the bottom surface in the third direction, and
the pair of inside surfaces are connected to the top surface.

### Clause 8

The semiconductor device according to Clause 6 or 7, wherein the recess includes an intermediate surface facing in the second direction and located between the pair of inside surfaces in the first direction,
the recess includes a first recess recessed from the first side surface and a second recess recessed from the intermediate surface of the first recess, and
a length of the second recess in the first direction is smaller than a length of the first recess in the first direction.

### Clause 9

The semiconductor device according to Clause 8, wherein a length of the second recess in the second direction is smaller than a length of the first recess in the second direction.

### Clause 10

The semiconductor device according to any one of Clauses 3 to 5, wherein the recess is recessed from the bottom surface, and
the pair of inside surfaces are connected to the first side surface.

### Clause 11

The semiconductor device according to any one of Clauses 3 to 5, wherein the recess is recessed from the first side surface and the bottom surface, and
the pair of inside surfaces are connected to the first side surface and the bottom surface.

### Clause 12

The semiconductor device according to any one of Clauses 2 to 11, wherein the recess includes a plurality of regions located along the first direction.

### Clause 13

The semiconductor device according to any one of Clauses 2 to 12, wherein the first lead and the second lead are exposed from the bottom surface.

### Clause 14

The semiconductor device according to Clause 13, wherein the first lead and the second lead are exposed from the first side surface.

### Clause 15

The semiconductor device according to Clause 13 or 14, further comprising: a second semiconductor element including an operational amplifier and electrically connected to the first semiconductor element; and
a die pad on which the first semiconductor element and the second semiconductor element are mounted,
wherein the second semiconductor element and the die pad are covered with the sealing resin, and
the die pad is spaced apart from the bottom surface.

### Clause 16

The semiconductor device according to Clause 15, further comprising a plurality of third leads located opposite to the first lead and the second lead in the second direction with respect to the die pad,
wherein the first semiconductor element and the second semiconductor element are electrically connected to one of the plurality of third leads,
a portion of each of the plurality of third leads is covered with the sealing resin, and
the plurality of third leads are exposed from the bottom surface.

### Clause 17

The semiconductor device according to Clause 16, wherein the sealing resin includes a second side surface facing away from the first side surface in the second direction, and
the plurality of third leads are exposed from the second side surface.

### REFERENCE NUMERALS

A10, A20, A30, A40, A50, A60, A70: Semiconductor device
10: Die pad 10A: First pad
10B: Second pad 11: Mounting surface
21: First lead 211: First obverse surface
212: First reverse surface 213: First end surface
22: Second lead 221: Second obverse surface
222: Second reverse surface 223: Second end surface
23: Third lead 23A: First terminal
23B: Second terminal 23C: Third terminal
23D: Fourth terminal 231: Third obverse surface
232: Third reverse surface 233: Third end surface
24: Fourth lead 241: Fourth obverse surface
242: Fourth reverse surface 243: Fourth end surface
244: Connecting surface 31: First semiconductor element
311: First electrode 32: Second semiconductor element
321: Second electrode 39: Bonding layer
41: First wire 42: Second wire
43: Third wire 44: Fourth wire
50: Sealing resin 51: Top surface
52: Bottom surface 531: First side surface
532: Second side surface 533: Third side surface
534: Fourth side surface 541: First overhang surface
542: Second overhanging surface 55: Recess
55A: First recess 55B: Second recess
551: Inside surface 552: Intermediate surface
x: First direction y: Second direction z: Third direction

1. A semiconductor device comprising:
a first semiconductor element formed with a step-down circuit;
a first lead electrically connected to the first semiconductor element;
a second lead electrically connected to the first semiconductor element and spaced apart from the first lead in a first direction; and
a sealing resin covering the first semiconductor element and a portion of each of the first lead and the second lead,
wherein the sealing resin includes a recess formed between the first lead and the second lead in the first direction, and
the recess overlaps with the first lead and the second lead as viewed in the first direction.

2. The semiconductor device according to claim 1, wherein the sealing resin includes a first side surface facing in a second direction orthogonal to the first direction and a bottom surface facing in a third direction orthogonal to the first direction and the second direction, and
the recess is recessed from at least one of the first side surface and the bottom surface.

3. The semiconductor device according to claim 2, wherein the recess includes a pair of inside surfaces facing each other in the first direction.

4. The semiconductor device according to claim 3, wherein a length of each of the pair of inside surfaces in the second direction is greater than a length of each of the first lead and the second lead in the second direction.

5. The semiconductor device according to claim 3, wherein a length of each of the pair of inside surfaces in the third direction is greater than a length of each of the first lead and the second lead in the third direction.

6. The semiconductor device according to claim 3, wherein the recess is recessed from the first side surface, and
the pair of inside surfaces are connected to the bottom surface.

7. The semiconductor device according to claim 6, wherein the sealing resin includes a top surface facing away from the bottom surface in the third direction, and
the pair of inside surfaces are connected to the top surface.

8. The semiconductor device according to claim 6, wherein the recess includes an intermediate surface facing in the second direction and located between the pair of inside surfaces in the first direction,
the recess includes a first recess recessed from the first side surface and a second recess recessed from the intermediate surface of the first recess, and
a length of the second recess in the first direction is smaller than a length of the first recess in the first direction.

9. The semiconductor device according to claim 8, wherein a length of the second recess in the second direction is smaller than a length of the first recess in the second direction.

10. The semiconductor device according to claim 3, wherein the recess is recessed from the bottom surface, and
the pair of inside surfaces are connected to the first side surface.

11. The semiconductor device according to claim 3, wherein the recess is recessed from the first side surface and the bottom surface, and
the pair of inside surfaces are connected to the first side surface and the bottom surface.

12. The semiconductor device according to claim 2, wherein the recess includes a plurality of regions located along the first direction.

13. The semiconductor device according to claim 2, wherein the first lead and the second lead are exposed from the bottom surface.

14. The semiconductor device according to claim 13, wherein the first lead and the second lead are exposed from the first side surface.

15. The semiconductor device according to claim 13, further comprising: a second semiconductor element including an operational amplifier and electrically connected to the first semiconductor element; and
a die pad on which the first semiconductor element and the second semiconductor element are mounted,
wherein the second semiconductor element and the die pad are covered with the sealing resin, and
the die pad is spaced apart from the bottom surface.

16. The semiconductor device according to claim 15, further comprising a plurality of third leads located opposite to the first lead and the second lead in the second direction with respect to the die pad,
wherein the first semiconductor element and the second semiconductor element are electrically connected to one of the plurality of third leads,
a portion of each of the plurality of third leads is covered with the sealing resin, and
the plurality of third leads are exposed from the bottom surface.

17. The semiconductor device according to claim 16, wherein the sealing resin includes a second side surface facing away from the first side surface in the second direction, and
the plurality of third leads are exposed from the second side surface.
